(19) United States
(12) Patent Application Publication
(10) Pub. No.: US 2019/0078940 A1
(43) Pub. Date: Mar. 14, 2019

(54) TEMPERATURE SENSING CIRCUIT

(71) Applicant: SK hynix Inc., Gyeonggi-do (KR)

(72) Inventors: Suk Hwan CHOI, Gyeonggi-do (KR); Chan Hui JEONG, Gyeonggi-do (KR); Young Sub YUK, Gyeonggi-do (KR)

(21) Appl. No.: 15/962,526

(22) Filed: Apr. 25, 2018

(30) Foreign Application Priority Data
Sep. 13, 2017 (KR) 10-2017-0116946

(51) Int. Cl. G01K 1/02; G01K 15/00; G11C 16/26; G11C 16/30; G11C 16/34; G11C 7/04

(52) U.S. Cl. CPC G01K 1/028; G01K 15/005; G11C 7/04; G11C 16/30; G11C 16/3459; G11C 16/26

(57) ABSTRACT

Provided herein is temperature sensing circuit. The temperature sensing circuit may include a bandgap voltage generation circuit configured to generate first to third reference voltages independent of temperature change, a temperature compensation circuit configured to output a compensation voltage based on a temperature depending on the first reference voltage, a fixed voltage generation circuit configured to generate fixed voltages independent of the temperature change depending on the second and third reference voltages, and a converter configured to output a temperature code in response to the compensation voltage and the fixed voltages.

### CROSS-REFERENCE TO RELATED APPLICATION

The present application claims priority to Korean patent application number 10-2017-0116946, filed on Sep. 13, 2017, which is incorporated herein by reference in its entirety.

### BACKGROUND

### 1. Field

Various embodiments of the present disclosure generally relate to a temperature sensing circuit. Particularly, various embodiments of the present disclosure relate to a temperature sensing circuit that can output a temperature code depending on temperature.

### 2. Description of the Related Art

A memory system may include a memory device in which data is stored and a memory controller which controls communication between the memory device and a host. For example, the memory system may perform a program operation, a read operation or an erase operation in response to a command received from the host. In order for the memory system to perform a specific operation in response to the command, voltages may be set in advance according to the environment in which the memory system is operated.

The memory system may include a plurality of transistors, which may be highly temperature dependent. For example, the electrical characteristics of transistors may vary depending on temperature. Accordingly, the memory system may be provided with a temperature sensing circuit for converting temperature into a temperature code and outputting the temperature code.

The temperature sensing circuit may operate after being supplied with a supply voltage. However, when the supply voltage is unstable, the reliability of the temperature code outputted from the temperature sensing circuit may deteriorate.

### SUMMARY

Various embodiments of the present disclosure are directed to a temperature sensing circuit, which can stably output a temperature code even if the supply voltage is unstable.

An embodiment of the present disclosure may provide a temperature sensing circuit. The temperature sensing circuit may include a bandgap voltage generation circuit configured to generate first to third reference voltages independent of temperature change, a temperature compensation circuit configured to output a compensation voltage based on a temperature depending on the first reference voltage, a fixed voltage generation circuit configured to generate fixed voltages independent of the temperature change depending on the second and third reference voltages, and a converter configured to output a temperature code in response to the compensation voltage and the fixed voltages.

An embodiment of the present disclosure may provide a temperature sensing circuit. The temperature sensing circuit may be configured to be supplied with a supply voltage, internally generate a feedback voltage in response to a first reference voltage independent of temperature change, and generate a compensation voltage based on a temperature. Further, the temperature sensing circuit may be configured to generate substantially constant fixed voltages in response to second and third reference voltages that are independent of the temperature change, convert the compensation voltage and the fixed voltages into a temperature code and output the temperature code, and when noise occurs in the supply voltage, remove the noise from the compensation voltage based on the feedback voltage.

### BRIEF DESCRIPTION OF THE DRAWINGS

FIG. 1 is a diagram illustrating a temperature sensing circuit according to an embodiment of the present disclosure.

FIG. 2 shows an exemplary configuration of a temperature compensation circuit of FIG. 1 according to one embodiment.

FIG. 3 shows an exemplary configuration of a fixed voltage generation circuit of FIG. 1 according to one embodiment.

FIG. 4 is a diagram illustrating a noise removal method using a resistor-capacitor (RC) filter of FIG. 3.

FIG. 5 is a diagram illustrating a memory system according to an embodiment of the present disclosure.

FIG. 6 is a diagram illustrating a method of operating a memory system according to an embodiment of the present disclosure.

FIG. 7 is a diagram illustrating a memory system according to an embodiment of the present disclosure.

FIGS. 8 to 11 are diagrams illustrating various embodiments of the memory system.

### DETAILED DESCRIPTION

Advantages and features of the present disclosure, and methods for achieving the same will be cleared with reference to embodiments described later in detail together with the accompanying drawings. Accordingly, the present disclosure is not limited to the following embodiments but embodied in other types. Rather, these embodiments are provided so that the present disclosure will be thorough and complete, and will fully convey the technical spirit of the disclosure to those skilled in the art.

It will be understood that when an element is referred to as being “coupled” or “connected” to another element, it can be directly coupled or connected to the other element or intervening elements may be present therebetween. In the specification, when an element is referred to as “comprising” or “including” a component, it does not preclude another component but may further include other components unless the context clearly indicates otherwise.

The drawings are not necessarily to scale and, in some instances, proportions may have been exaggerated in order to clearly illustrate features of the embodiments.

The terminology used herein is for the purpose of describing particular embodiments only and is not intended to be limiting of the present invention.

As used herein, singular forms may include the plural forms as well, unless the context clearly indicates otherwise.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

Hereinafter, the various embodiments of the present invention will be described in detail with reference to the attached drawings.

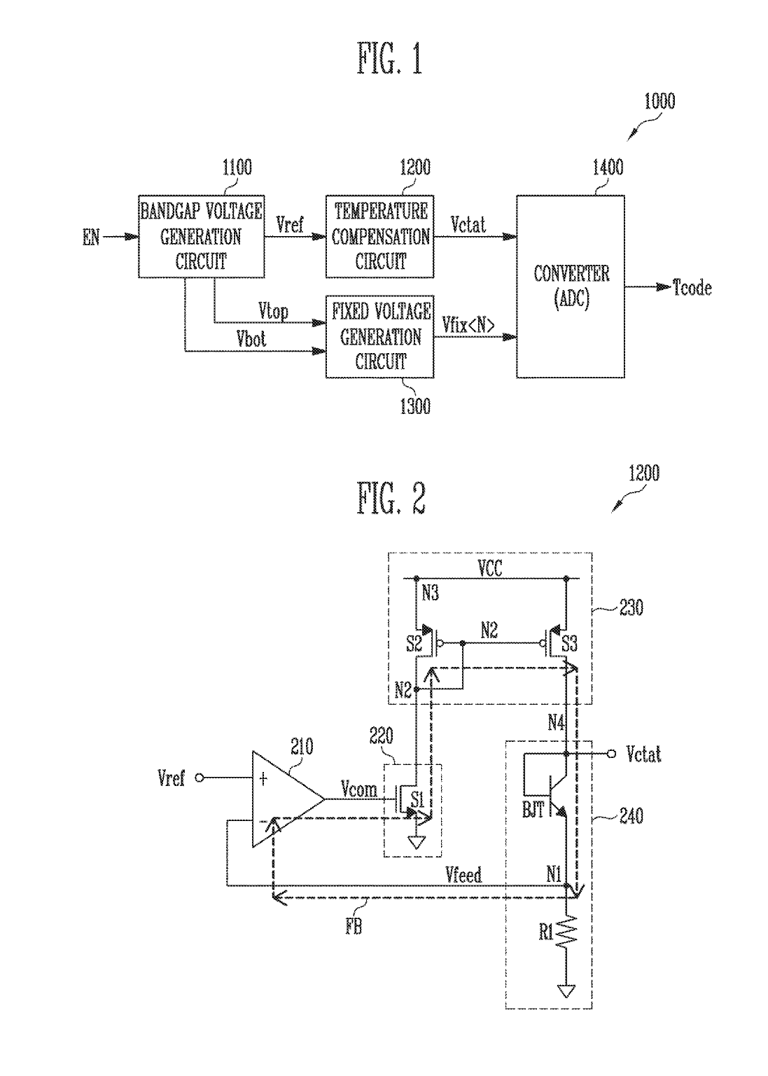

FIG. 1 is a diagram illustrating a temperature sensing circuit according to an embodiment of the present disclosure.

Referring to FIG. 1, a temperature sensing circuit 1000 may convert a temperature into a temperature code Tcode and output the temperature code Tcode. To this end, the temperature sensing circuit 1000 may include a bandgap voltage generation circuit 1100, a temperature compensation circuit 1200, a fixed voltage generation circuit 1300, and a converter 1400.

The bandgap voltage generation circuit 1100 may generate a constant voltage regardless of temperature change. For example, the bandgap voltage generation circuit 1100 may perform a temperature sensing operation when an enable signal EN is activated. The bandgap voltage generation circuit 1100 may output the first to third reference voltages Vref, Vtop, and Vbot which are maintained at constant levels regardless of temperature change. The first to third reference voltages Vref, Vtop, and Vbot may be outputted at different levels. For example, the bandgap voltage generation circuit 1100 may include a circuit for generating a voltage proportional to temperature and a circuit for generating a voltage inversely proportional to temperature to generate constant voltages regardless of temperature change. When the voltages outputted from the circuits are summed, the bandgap voltage generation circuit 1100 may generate the first to third reference voltages Vref, Vtop, and Vbot which are maintained at constant levels regardless of temperature change. For example, the bandgap voltage generation circuit 1100 may generate the first reference voltage Vref, and then generate the second and third reference voltages Vtop and Vbot by dividing the first reference voltage Vref. For example, all of the first to third reference voltages Vref, Vtop, and Vbot may be positive voltages, and the second reference voltage Vtop may be less than the first reference voltage Vref, while the third reference voltage Vbot may be less than the second reference voltage Vtop. The circuits for generating voltages proportional to or inversely proportional to temperature in this way may be implemented in various forms including any suitable hardware circuit elements adapted to output reference voltages depending on temperature.

The temperature compensation circuit 1200 may be supplied with a supply voltage from an external device, may be operated depending on the first reference voltage Vref, and may output a compensation voltage Vctat inversely proportional to temperature change. For example, the temperature compensation circuit 1200 may output the compensation voltage Vctat, the level of which is decreased as temperature is increased and the level of which is increased as temperature is decreased.

The fixed voltage generation circuit 1300 may be operated depending on the second and third reference voltages Vtop and Vbot, and may output fixed voltages Vfix<N>, which are constant regardless of temperature change.

The converter 1400 may output a temperature code Tcode in response to the fixed voltages Vfix<N> which are constant regardless of temperature change, and the compensation voltage Vctat which is inversely proportional to the temperature change. The converter 1400 may be implemented as an analog-to-digital converter (ADC) for converting an analog signal into a digital signal. The ADC may include any suitable hardware circuit elements adapted to receive the compensation voltage Vctat and the fixed voltage Vfix<N> and output a corresponding digital code.

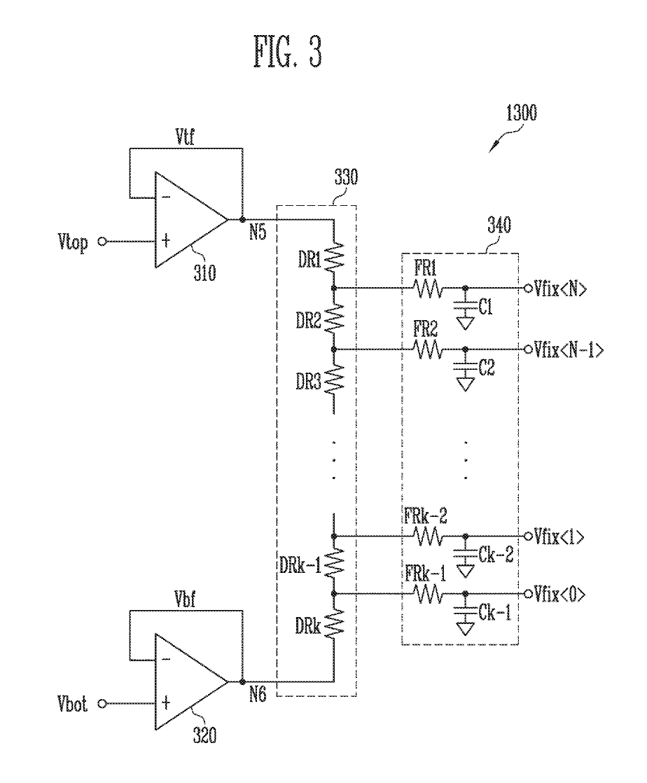

Among the bandgap voltage generation circuit 1100, the temperature compensation circuit 1200, the fixed voltage generation circuit 1300, and the converter 1400 as described above, the temperature compensation circuit 1200 is described in more detail below with reference to FIG. 2, and the fixed voltage generation circuit 1300 is described in more detail below with reference to FIG. 3.

FIG. 2 is an exemplary configuration of the temperature compensation circuit of FIG. 1 according to one embodiment.

Referring to FIG. 2, the temperature compensation circuit 1200 may include a first amplifier 210, a first current path circuit 220, a mirror circuit 230, and a second current path circuit 240.

The first amplifier 210 may output a comparative voltage Vcom by comparing a first reference voltage Vref with a feedback voltage Vfeed. For example, the first reference voltage Vref may be applied to the positive terminal (+) of the first amplifier 210, and the feedback voltage Vfeed may be applied to the negative terminal (−) of the first amplifier 210. For example, the negative terminal (−) of the first amplifier 210 may be coupled to a first node N1, and the feedback voltage Vfeed may be applied to the negative terminal (−) of the first amplifier 210 through the first node N1.

In accordance with one exemplary embodiment, the first amplifier 210 may output a comparative voltage Vcom having a positive level when the feedback voltage Vfeed is higher than the first reference voltage Vref, and may output a comparative voltage Vcom having a negative level when the feedback voltage Vfeed is lower than the first reference voltage Vref. Here, the feedback voltage Vfeed is a voltage that is fed back on a feedback path in the temperature compensation circuit 1200, which is described in detail below.

The first current path circuit 220 may be implemented as a first transistor S1. The first transistor S1 may be implemented as an NMOS transistor, wherein the gate of the first transistor S1 may be coupled to the output terminal of the first amplifier 210, and the drain and source of the first transistor S1 may be coupled to a second node N2 and a ground terminal, respectively. Therefore, the first transistor S1 may allow current corresponding to the comparative voltage Vcom that is applied to the gate to flow therethrough. For example, as the level of the comparative voltage Vcom is increased, a larger amount of current may flow through the first transistor S1. In contrast, as the level of the comparative voltage Vcom is decreased, a smaller amount of current may flow through the first transistor S1. More specifically, the amount of current of the first current path circuit 220 may vary with the comparative voltage Vcom. That is, as the level of the comparative voltage Vcom is increased, the amount of current flowing through the first transistor S1 may be increased. As the level of the comparative voltage Vcom is decreased, the amount of current flowing through the first transistor S1 may be decreased.

The mirror circuit 230 may include the second and third transistors S2 and S3 coupled in a mirror structure. For example, each of the second and third transistors S2 and S3 may be implemented as a PMOS transistor. The gate and drain of the second transistor S2 may be coupled in common to the second node N2, and the source of the second transistor S2 may be coupled to a third node N3. A supply voltage VCC may be applied to the third node N3. For example, the voltage of the second node N2 may be increased or decreased by the first current path circuit 220. The higher the voltage of the second node N2 becomes, the lower the turn-on levels of the second and third transistors S2 and S3 becomes. Further, the lower the voltage of the second node N2 becomes, the higher the turn-on levels of the second and third transistors S2 and S3 becomes. Therefore, when the first transistor S1 is turned on, a current path may be formed through the first and second transistors S1 and S2, and thus the voltage of the second node N2 may be varied in an analog form.

The gate of the third transistor S3 may be coupled to the second node N2, the source of the third transistor S3 may be coupled to the third node N3, and the drain of the third transistor S3 may be coupled to a fourth node N4. Therefore, the turn-on levels of the second and third transistors S2 and S3 may be equally varied depending on the voltage of the second node N2, so that the amounts of current flowing through the second and fourth nodes N2 and N4 may be mirrored to be equal to each other. That is, the voltage of the second node N2 may be reflected in the fourth node N4.

The second current path circuit 240 may include, for example, a bipolar junction transistor (BJT) and a first resistor R1. The BJT and the first resistor R1 may be coupled in series between the fourth node N4 and the ground terminal to form a current path. For example, the BJT may be coupled between the fourth node N4 and the first node N1, and the first resistor R1 may be coupled between the first node N1 and the ground terminal.

The BJT may be implemented, for example, as an NPN-type transistor. In accordance with one exemplary embodiment, the base and collector of the BJT may be coupled in common to the fourth node N4. The emitter of the BJT may be coupled to the first node N1. When the current path is formed in the second current path circuit 240, a voltage inversely proportional to temperature is formed between both ends of the BIT (e.g., the collector and the emitter), and thus the voltage of the fourth node N4 may be output as a compensation voltage Vctat inversely proportional to temperature.

The first resistor R1 may be used to stably maintain the voltage that is applied to the first node N1. That is, the feedback voltage Vfeed that is applied to the first node N1 may be maintained at a constant level in response to the current generated from the BJT.

The voltage applied to the first node N1 becomes the feedback voltage Vfeed, and the feedback voltage Vfeed is applied back to the negative terminal (−) of the first amplifier 210. That is, a feedback loop may be formed through the first amplifier 210, the first current path circuit 220, the mirror circuit 230, and the second current path 240, and a feedback voltage Vfeed may continue to be regenerated via the feedback loop. When the feedback voltage Vfeed is increased above the reference voltage Vref, the comparative voltage Vcom outputted from the first amplifier 210 may be decreased according to one exemplary embodiment. When the comparative voltage Vcom is decreased, the turn-on level of the first transistor S1 is decreased, and thus the feedback voltage Vfeed may be decreased as well closer to the reference voltage Vref while the current flowing through the first and fourth nodes N1 and N4 is decreased. Therefore, the fourth node N4 may be maintained at substantially the same level as the reference voltage Vref. Accordingly, when noise occurs in the supply voltage VCC, the voltages of the second and fourth nodes N2 and N4 may be temporarily influenced by the noise in the early stage of noise occurrence, but the temperature compensation circuit 1200 may rapidly and stably recover the compensation voltage Vctat based on the feedback voltage Vfeed via a feedback loop FB.

FIG. 3 is an exemplary configuration of the fixed voltage generation circuit of FIG. 1 according to one embodiment.

Referring to FIG. 3, the fixed voltage generation circuit 1300 may include a second amplifier 310, a third amplifier 320, a voltage division circuit 330, and a filter 340.

The second amplifier 310 may output a first input voltage Vtf through a fifth node N5 by comparing a second reference voltage Vtop with the first input voltage Vtf. That is, the output terminal of the second amplifier 310 may be coupled to the fifth node N5, and the fifth node N5 may be coupled to the negative terminal (−) of the second amplifier 310. Therefore, the first input voltage Vtf may be outputted from the second amplifier 310 at the same time that it may be fed back to the negative terminal (−) of the second amplifier 310. The second reference voltage Vtop may be applied to the positive terminal (+) of the second amplifier 310. Therefore, when the first input voltage Vtf is lower than the second reference voltage Vtop, the level of the first input voltage Vtf may be increased, whereas when the first input voltage Vtf is higher than the second reference voltage Vtop, the level of the first input voltage Vtf may be decreased.

The third amplifier 320 may output a second input voltage Vbf through a sixth node N6 by comparing a third reference voltage Vbot with the second input voltage Vbf. That is, the output terminal of the third amplifier 320 may be coupled to the sixth node N6, and the sixth node N6 may be coupled to the negative terminal (−) of the third amplifier 320. Therefore, the second input voltage Vbf may be outputted from the third amplifier 320 at the same time that it may be fed back to the negative terminal (−) of the third amplifier 320. The third reference voltage Vbot may be applied to the positive terminal (+) of the third amplifier 320. Therefore, when the second input voltage Vbf is lower than the third reference voltage Vbot, the level of the second input voltage Vbf may be increased, whereas when the second input voltage Vbf is higher than the third reference voltage Vbot, the level of the second input voltage Vbf may be decreased.

The second and third reference voltages Vtop and Vbot are positive voltages generated by a bandgap voltage generation circuit (e.g., 1100 of FIG. 1), and may be maintained at constant levels regardless of temperature changes. For example, the second reference voltage Vtop may be higher than the third reference voltage Vbot. For example, when the second reference voltage Vtop is 1.15 V, the third reference voltage Vbot may be 0.4 V.

The voltage division circuit 330 may include first to k-th divider resistors DR1 to DRk coupled in series between the fifth node N5 and the sixth node N6. The first to k-th divider resistors DR1 to DRk may be resistors having the same resistance value or different resistance values. When the first input voltage Vtf is applied to the fifth node N5, and the second input voltage Vbf is applied to the sixth node N6, the voltage may be divided by the first to k-th divider resistors DR1 to DRk, and then different divided voltages may be applied to the nodes between the first to k-th divider resistors DR1 to DRk.

The filter 340 may output first to N+1-th fixed voltages Vfix<0> to Vfix<N> by removing noise from the divided voltages generated by the voltage division circuit 330. For example, the filter 340 may be implemented, for example, as a resistor-capacitor (RC) filter. The RC filter may include first to k−1-th filter resistors FR1 to FRk−1 and first to k−1-th capacitors C1 to Ck−1. In accordance with one exemplary embodiment, the first to k−1-th filter resistors FR1 to FRk−1 and the first to k−1-th capacitors C1 to Ck−1 may be coupled in series between nodes between the first to k-th divider resistors DR1 to DRk and ground terminals. For example, the first filter resistor FR1 may be coupled to a node between the first divider resistor DR1 and the second divider resistor DR2, and the first capacitor C1 may be coupled between the first filter resistor FR1 and the ground terminal. The N+1-th fixed voltage Vfix<N> may be the voltage of a node for coupling the first filter resistor FR1 to the first capacitor C1. The k−1-th filter resistor FRk−1 may be coupled to a node between the k−1-th divider resistor DRk−1 and the k-th divider resistor DRk, and the k−1-th capacitor Ck−1 may be coupled between the k−1-th filter resistor FRk−1 and the ground terminal. The first fixed voltage Vfix<0> may be the voltage of a node for coupling the k−1-th filter resistor FRk−1 and the k−1-th capacitor Ck−1. In this way, the first to k−1-th filter resistors FR1 to FRk−1 and the first to k−1-th capacitors C1 to Ck−1 may be coupled between the first to k-th divider resistors DR1 to DRk. The first to N+1-th fixed voltages Vfix<0> to Vfix<N> may be outputted from the nodes for coupling the first to k−1-th filter resistors FR1 to FRk−1 to the first to k−1-th capacitors C1 to Ck−1.

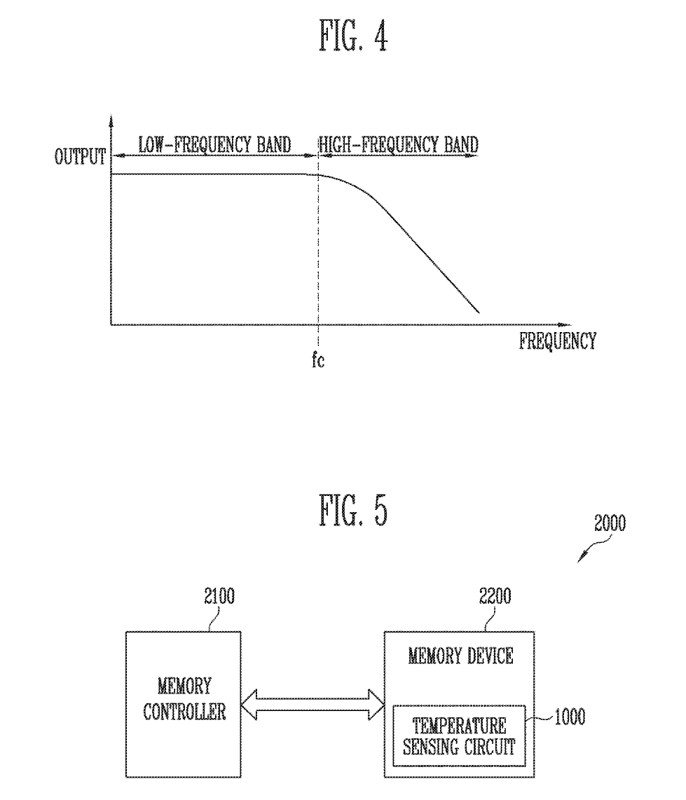

That is, the first to N+1-th fixed voltages Vfix<0> to Vfix<N> may be voltages obtained by removing noise from the divided voltages between the first to k-th divider resistors DR1 to DRk. A method of removing noise is described in detail below with reference to FIG. 4.

FIG. 4 is a diagram illustrating a noise removal method using the RC filter of FIG. 3.

Referring to FIG. 4, the RC filter may mainly remove, for example, high-frequency components of noise through first to k−1-th filter resistors FR1 to FRk−1 and first to k−1-th capacitors C1 to Ck−1. Therefore, with respect to a critical frequency fc, a voltage outputted in a low-frequency band lower than the critical frequency fc, among voltages inputted to the RC filter, may be maintained, but a voltage outputted in a high-frequency band higher than the critical frequency fc may be decreased, and thus noise in the high-frequency band may be removed from the output voltages.

FIG. 5 is a diagram illustrating a memory system according to an embodiment of the present disclosure.

Referring to FIG. 5, the above-described temperature sensing circuit 1000 may be included in a memory device 2200 in which data is stored. For example, the memory device 2200 may perform a program operation, a read operation, or an erase operation under the control of a memory controller 2100, and may transmit read data to the memory controller 2100. Although FIG. 5 shows that the temperature sensing circuit 1000 is included in the memory device 2200 by way of example, the temperature sensing circuit 1000 may be included in other types of memory devices such as, e.g., a processor, a micro-control unit, and a telecommunication chip included in an electronic system according to various embodiments of the present disclosure.

When a command for a selected operation is received by the memory device 2200 from the memory controller 2100, the temperature sensing circuit 1000 included in the memory device 2200 may output a temperature code (e.g., Tcode of FIG. 1) depending on temperature. During the generation of the temperature code Tcode, the memory device 2200 may perform a pumping operation for generating a voltage required for the selected operation, simultaneously with a temperature code generation operation. As a result, the time required to generate an operating voltage may be shortened. An embodiment of the operation of the memory system 2000 is described in detail below.

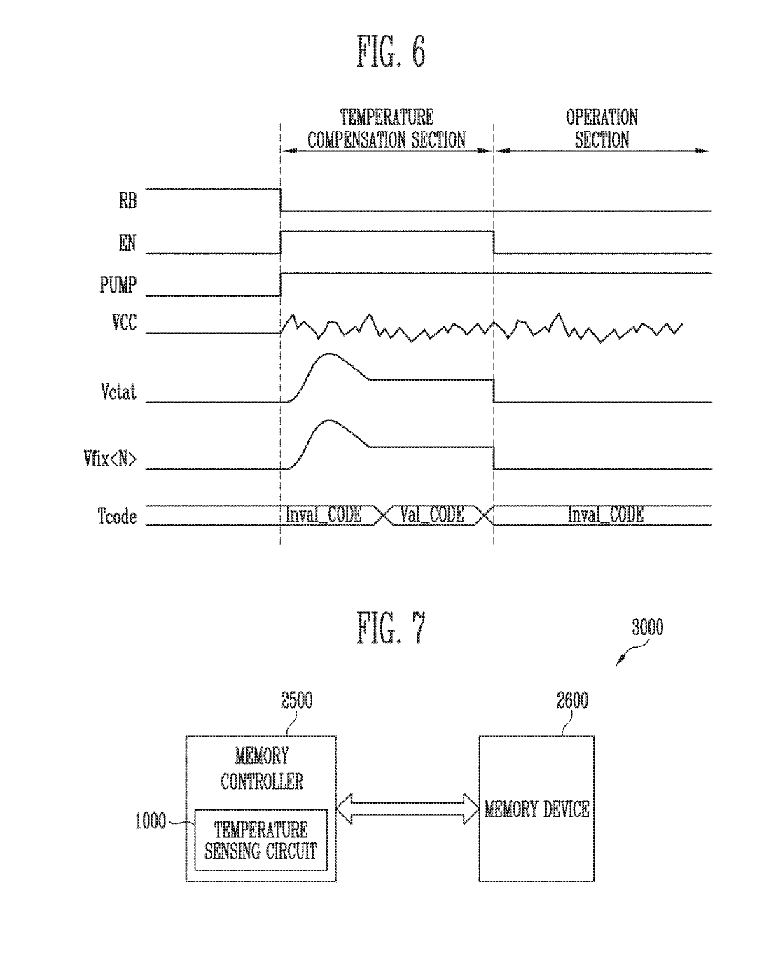

FIG. 6 is a diagram illustrating a method of operating a memory system according to an embodiment of the present disclosure.

Referring to FIG. 6, when a memory device (e.g., 2200 of FIG. 5) receives a command from a memory controller (e.g., 2100 of FIG. 5), the temperature sensing circuit 1000 may generate a temperature code Tcode during a temperature compensation section. Here, when the temperature compensation section is initiated, the memory device 2200 may output a ready/busy signal RB at low level to initiate a selected operation, and may start a pumping operation PUMP to generate an operating voltage. That is, a temperature compensation operation for generating the temperature code Tcode and the pumping operation PUMP for generating the operating voltage may be simultaneously performed. When the pumping operation is initiated, noise may occur in a supply voltage VCC. The temperature sensing circuit 1000 may be temporarily influenced by initial noise of the supply voltage VCC. For example, a fixed voltage Vfix<N> and a compensation voltage Vctat may rapidly increased. At this time, the temperature code Tcode, which is outputted from the temperature sensing circuit 1000, may be processed as an invalid code Inval_CODE. However, the temperature sensing circuit 1000 may stably output again the fixed voltage Vfix<N> and the compensation voltage Vctat even if noise is present in the supply voltage VCC. The temperature code Tcode outputted at that time may be processed as a valid code Val_CODE and may then be used in the memory device. When the valid code Val_CODE is generated and the pumping operation is terminated, an enable signal EN that is applied to the temperature sensing circuit 1000 is deactivated, and neither the fixed voltage Vfix<N> nor the compensation voltage Vctat is outputted. Therefore, when an operation section is initiated, all temperature codes Tcode are processed as invalid codes Inval_CODE, and the actual operation section of the memory device 2200 may be started. For example, the memory device 2200 may perform a program operation, a read operation, or an erase operation.

In the case that the temperature sensing circuit 1000 according to one embodiment of the present disclosure is not used, when noise occurs in the supply voltage VCC during a temperature compensation section, the temperature code Tcode may be influenced and may then be processed as an invalid code Inval_CODE, and thus the pumping operation of the memory device 2200 is initiated after all valid codes Val_CODE have been outputted. However, the temperature sensing circuit 1000 according to one embodiment of the present disclosure can help output a valid code Val_CODE more quickly even if noise is present in the supply voltage VCC. Accordingly, since the pumping operation of the memory device 2200 may be performed simultaneously with the temperature compensation operation during the temperature compensation section, the operating time of the memory device 2200 may be shortened.

FIG. 7 is a diagram illustrating a memory system according to an embodiment of the present disclosure.

Referring to FIG. 7, a memory system 3000 may include a memory controller 2500 and a memory device 2600. In an embodiment illustrated in FIG. 7, a temperature sensing circuit 1000 may be included in the memory controller 2500, unlike the memory system 2000 illustrated in FIG. 5. Since the temperature sensing circuit 1000 has been described in detail in FIG. 1, a detailed description thereof will be omitted. For example, when a temperature code Tcode is generated in the memory controller 2500, the memory controller 2500 may generate a valid temperature code even while a normal operation is performed, thus shortening the operating time of the memory controller 2500.

In addition, the temperature sensing circuit 1000 may be included in each of the memory controller 2500 and the memory device 2600, and may also be used in various electronic devices other than the memory system. That is, the temperature sensing circuit 1000 may be included in various types of memory devices such as, e.g., a processor, a micro-control unit, and a telecommunication chip included in an electronic system according to one or more embodiments of the present disclosure.

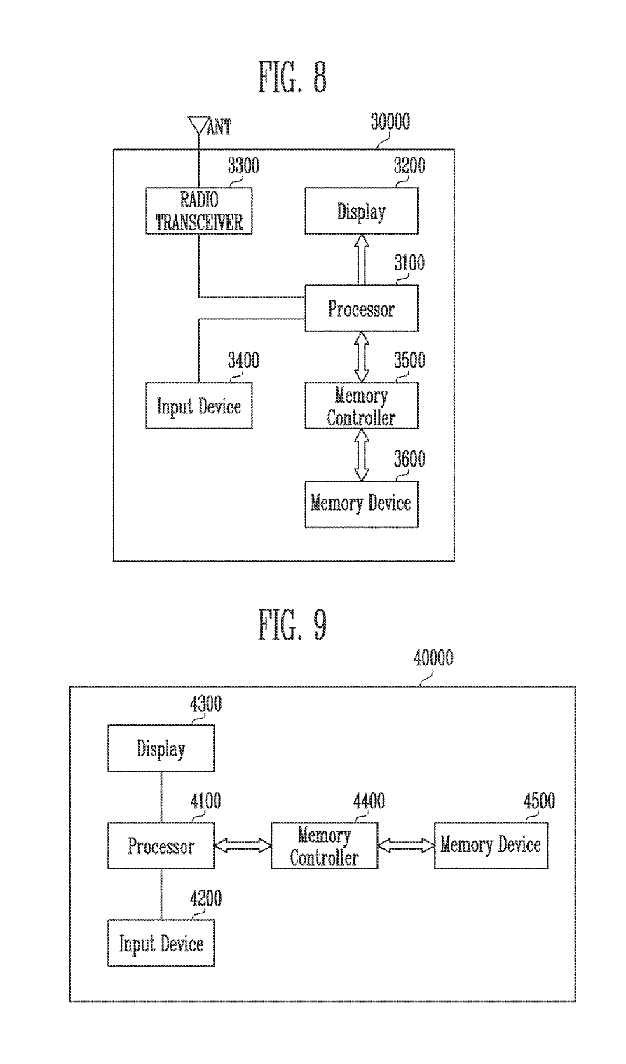

FIGS. 8 to 11 are diagrams illustrating memory systems according to various embodiments of the present disclosure.

Referring to FIG. 8, a memory system 30000 may be implemented as a cellular phone, a smart phone, a tablet PC, a personal digital assistant (PDA) or a wireless communication device. The memory system 30000 may include a memory device 3600 and a memory controller 3500 that is capable of controlling the operation of the memory device 3600. Here, the memory controller 3500 and the memory device 3600 may be respectively implemented as the memory controller 2100 or 2500 and the memory device 2200 or 2600, described above with reference to FIG. 5 or 7.

The memory controller 3500 may control a data access operation for the memory device 3600, for example, a program operation, an erase operation or a read operation under the control of a processor 3100.

Data programmed to the memory device 3600 may be outputted via a display 3200 under the control of the memory controller 3500.

A radio transceiver 3300 may exchange radio signals through an antenna ANT. For example, the radio transceiver 3300 may change a radio signal received through the antenna ANT into a signal which may be processed in the processor 3100. Therefore, the processor 3100 may process a signal outputted from the radio transceiver 3300 and transmit the processed signal to the memory controller 3500 or the display 3200. The memory controller 3500 may transmit the signal processed by the processor 3100 to the memory device 3600. Furthermore, the radio transceiver 3300 may change a signal outputted from the processor 3100 into a radio signal, and output the changed radio signal to an external device through the antenna ANT. An input device 3400 may be used to input a control signal for controlling the operation of the processor 3100 or data to be processed by the processor 3100. The input device 3400 may be implemented as a pointing device such as a touch pad or a computer mouse, a keypad or a keyboard. The processor 3100 may control the operation of the display 3200 such that data outputted from the memory controller 3500, data outputted from the radio transceiver 3300, or data outputted from the input device 3400 is outputted via the display 3200.

In an embodiment, the memory controller 3500 capable of controlling the operation of the memory device 3600 may be implemented as a part of the processor 3100 or a chip provided separately from the processor 3100.

Referring to FIG. 9, a memory system 40000 may be embodied in a personal computer, a tablet PC, a net-book, an e-reader, a personal digital assistant (PDA), a portable multimedia player (PMP), an MP3 player, or an MP4 player.

The memory system 40000 may include a memory device 4500 and a memory controller 4400 that is capable of controlling a data processing operation of the memory device 4500. Here, the memory controller 4400 and the memory device 4500 may be respectively implemented as the memory controller 2100 or 2500 and the memory device 2200 or 2600, described above with reference to FIG. 5 or 7.

A processor 4100 may output data stored in the memory device 4500 via a display 4300 according to data inputted from an input device 4200. For example, the input device 4200 may be implemented as a pointing device such as a touch pad or a computer mouse, a keypad or a keyboard.

The processor 4100 may control the overall operation of the memory system 40000 and control the operation of the memory controller 4400. In an embodiment, the memory controller 4400 capable of controlling the operation of the memory device 4500 may be implemented as a part of the processor 4100 or a chip provided separately from the processor 4100.

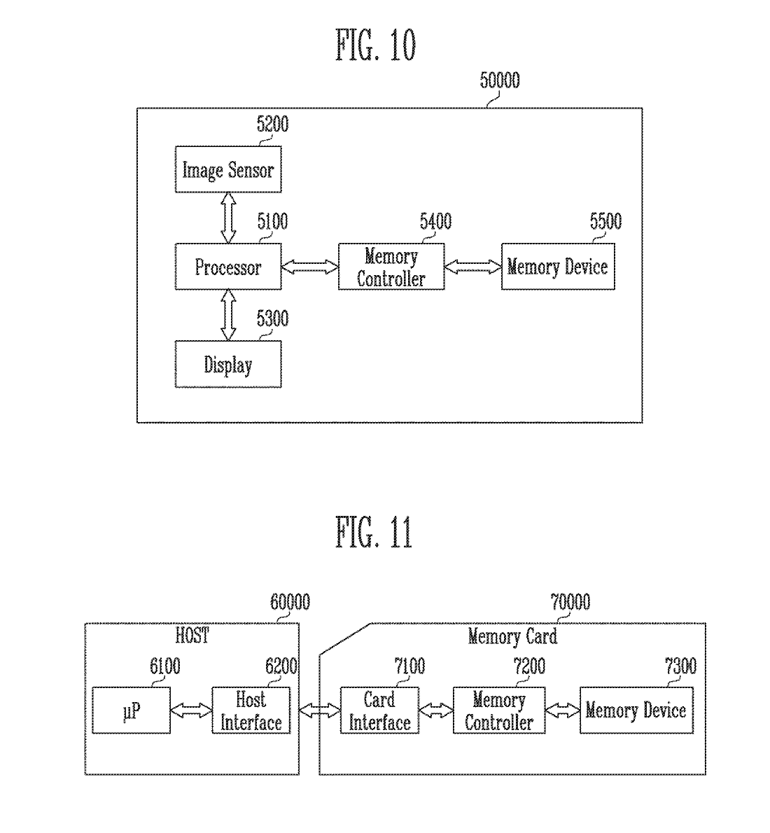

Referring to FIG. 10, a memory system 50000 may be embodied in an image processing device, e.g., a digital camera, a mobile phone provided with a digital camera, a smartphone provided with a digital camera, or a tablet PC provided with a digital camera.

The memory system 50000 may include a memory device 5500 and a memory controller 5400 that is capable of controlling a data processing operation of the memory device 5500, e.g., a program operation, an erase operation or a read operation. Further, the memory controller 5400 and the memory device 5500 may be respectively implemented as the memory controller 2100 or 2500 and the memory device 2200 or 2600, described above with reference to FIG. 5 or 7.

An image sensor 5200 of the memory system 50000 may convert an optical image into digital signals. The converted digital signals may be transmitted to a processor 5100 or the memory controller 5400. Under the control of the processor 5100, the converted digital signals may be outputted via a display 5300 or stored in the memory device 5500 through the memory controller 5400. Data stored in the memory device 5500 may be outputted via the display 5300 under the control of the processor 5100 or the memory controller 5400.

In an embodiment, the memory controller 5400 capable of controlling the operation of the memory device 5500 may be implemented as a part of the processor 5100, or a chip provided separately from the processor 5100.

Referring to FIG. 11, a memory system 70000 may be embodied in a memory card or a smart card. The memory system 70000 may include a memory device 7300, a memory controller 7200, and a card interface 7100. The memory controller 7200 and the memory device 7300 may be respectively implemented as the memory controller 2100 or 2500 and the memory device 2200 or 2600, described above with reference to FIG. 5 or 7.

The memory controller 7200 may control data exchange between the memory device 7300 and the card interface 7100. In an embodiment, the card interface 7100 may be, but is not limited to, a secure digital (SD) card interface or a multi-media card (MMC) interface.

The card interface 7100 may interface data exchange between a host 60000 and the memory controller 7200 according to a protocol of the host 60000. In an embodiment, the card interface 7100 may support a universal serial bus (USB) protocol and an inter-chip (IC)-USB protocol. Here, the card interface may refer to hardware capable of supporting a protocol which is used by the host 60000, software installed in the hardware, or a signal transmission method.

When the memory system 70000 is coupled to a host interface 6200 of the host 60000, such as a PC, a tablet PC, a digital camera, a digital audio player, a mobile phone, console video game hardware or a digital set-top box, the host interface 6200 may perform data communication with the memory device 7300 through the card interface 7100 and the memory controller 7200 under the control of a microprocessor (μP) 6100.

Various embodiments of the present disclosure are advantageous in that, even if a supply voltage is unstable, a temperature sensing circuit may stably output a temperature code.

Further, since the temperature sensing circuit may stably generate a temperature code, a memory system may perform a pumping operation for generating an operating voltage simultaneously with a temperature code generation operation during the generation of the temperature code, thus shortening the operating time of the memory system.

Examples of embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A temperature sensing circuit, comprising:
a bandgap voltage generation circuit configured to generate first to third reference voltages independent of temperature change;
a temperature compensation circuit configured to output a compensation voltage based on a temperature depending on the first reference voltage;
a fixed voltage generation circuit configured to generate fixed voltages independent of the temperature change depending on the second and third reference voltages; and
a converter configured to output a temperature code in response to the compensation voltage and the fixed voltages.

2. The temperature sensing circuit according to claim 1, wherein the bandgap voltage generation circuit is configured to:
generate the first reference voltage, and
generate the second and third reference voltages based on a division of the first reference voltage.

3. The temperature sensing circuit according to claim 1, wherein:
the first to third reference voltages are generated as positive voltages,
the second reference voltage is generated as a voltage lower than the first reference voltage, and
the third reference voltage is generated as a voltage lower than the second reference voltage.

4. The temperature sensing circuit according to claim 1, wherein the temperature compensation circuit is supplied with a supply voltage and is configured to output the compensation voltage inversely proportional to the temperature change in response to the first reference voltage.

5. The temperature sensing circuit according to claim 4, wherein the temperature compensation circuit comprises:
a first amplifier configured to output a comparative voltage based on a comparison of the first reference voltage with a feedback voltage applied to a first node;
a first current path circuit configured to allow an amount of current flowing therethrough to vary depending on the comparative voltage;
a mirror circuit coupled to a third node supplied with the supply voltage and configured to reflect an amount of current of a second node, which is adjusted depending on the comparative voltage, on a fourth node; and
a second current path circuit configured to output a voltage of the fourth node as the compensation voltage and output the feedback voltage to the first node.

6. The temperature sensing circuit according to claim 5, wherein:
the first reference voltage is applied to a positive terminal of the first amplifier, and
the feedback voltage is applied to a negative terminal of the first amplifier.

7. The temperature sensing circuit according to claim 5, wherein the first current path circuit comprises a first transistor configured to form a current path between the second node and a ground terminal in response to the comparative voltage.

8. The temperature sensing circuit according to claim 5, wherein:
the mirror circuit comprises second and third transistors coupled in parallel to the third node,
the second transistor is coupled between the third node and the second node and is operated in response to a voltage of the second node, and
the third transistor coupled between the third node and the fourth node and is operated in response to the voltage of the second node.

9. The temperature sensing circuit according to claim 5, wherein the second current path circuit comprises:
a bipolar junction transistor configured to generate, at the fourth node, a voltage inversely proportional to the temperature in response to a current generated from the third transistor; and
a first resistor configured to maintain the feedback voltage in response to the current generated from the third transistor.

10. The temperature sensing circuit according to claim 1, wherein the fixed voltage generation circuit comprises:
a second amplifier configured to output a first input voltage to a fifth node based on a comparison of the second reference voltage with the first input voltage;
a third amplifier configured to output a second input voltage to a sixth node based on a comparison of the third reference voltage with the second input voltage;
a voltage division circuit configured to divide a voltage applied between the fifth and sixth nodes; and
a filter configured to remove noise from divided voltages, generated by the voltage division circuit and to output fixed voltages.

11. The temperature sensing circuit according to claim 10, wherein:
the second reference voltage is applied to a positive terminal of the second amplifier, and
the first input voltage is applied to a negative terminal of the second amplifier.

12. The temperature sensing circuit according to claim 10, wherein:
the third reference voltage is applied to a positive terminal of the third amplifier, and
the second input voltage is applied to a negative terminal of the third amplifier.

13. The temperature sensing circuit according to claim 10, wherein the voltage division circuit comprises a plurality of divider transistors coupled in series between the fifth and sixth nodes.

14. The temperature sensing circuit according to claim 10, wherein the filter is implemented as a resistor-capacitor (RC) filter to remove noise from the divided voltages generated by the voltage division circuit.

15. The temperature sensing circuit according to claim 14, wherein the RC filter comprises filter resistors and capacitors configured to remove noise from the divided voltages generated by the voltage division circuit.

16. The temperature sensing circuit according to claim 1, wherein the converter is implemented as an analog-to-digital converter (ADC) configured to convert an analog signal into the temperature code that is a digital signal.

17. A temperature sensing circuit, wherein the temperature sensing circuit is configured to:
be supplied with a supply voltage, internally generate a feedback voltage in response to a first reference voltage independent of temperature change, and generate a compensation voltage based on a temperature,
generate substantially constant fixed voltages in response to second and third reference voltages that are independent of the temperature change,
convert the compensation voltage and the fixed voltages into a temperature code and output the temperature code, and
when noise occurs in the supply voltage, remove the noise from the compensation voltage based on the feedback voltage.

18. The temperature sensing circuit according to claim 17, comprising a temperature compensation circuit configured to be supplied with the supply voltage and to generate the compensation voltage inversely proportional to the temperature change in response to the first reference voltage.

19. The temperature sensing circuit according to claim 17, comprising a fixed voltage generation circuit configured to:
generate divided voltages in response to the second and third reference voltages, and
generate the fixed voltages based on removal of the noise from the divided voltages.

20. The temperature sensing circuit according to claim 17, comprising a converter configured to output the temperature code that is a digital signal in response to the compensation voltage and the fixed voltages that are analog signals.
